(19) United States
(12) Patent Application Publication
(10) Pub. No.: US 2003/0094964 A1
(43) Pub. Date: May 22, 2003

(54) Dut testing board

(76) Inventor: Andy Chen, Hsin Chu City (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 09/988,085

(22) Filed: Nov. 19, 2001

(51) Int. Cl. G01R 31/02

(52) U.S. Cl. 324/763

(57) ABSTRACT

An integrated circuit test apparatus includes a testing board having at least two divided test sites thereon and at least two devices under test (DUT) disposed on their corresponding test site respectively with at least one associated independent ground.

### BACKGROUND OF THE INVENTION

1. Field of the Invention

The present invention relates to a DUT (device under test) testing board, and more particularly, to a DUT testing board having separated test sites with at least one independent associated grounds for reducing interference during testing.

2. Description of the Prior Art

Semiconductor testing of ICs or chips is required at various stages during the fabrication process. Each IC must be individually tested in the wafer and in a packaged form manner to ensure that it functions as intended. As chips become more and more powerful and complicated, the needs of high-speed and accurate tests become more and more important accordingly.

A testing board is used to interface the DUTs (device-under-test). Typically, a number of DUTs are disposed on the testing board at the same time. FIG. 1 is a schematic diagram exemplarily showing configuration of two devices, DUT1 and DUT2. As shown in FIG. 1, the DUT1 and DUT 2 share the same signal ground DG and the power supply ground 2. The signal ground DG is for grounding signals, and the power supply ground 2 is for grounding the power supply.

FIG. 2 is a cross-sectional, schematic view illustrating a prior art testing board structure. The DUT1 and DUT2, for example, are mounted on the top plate (TOP) as known by those skilled in the art. Four interplates (IN1, IN2, IN3, and IN4) are mounted between the top plate (Top) and the bottom plate (BOT). Each of the four inter plates is disposed a data ground (DG). Furthermore, a first device power supply (DPS1) and a third device power supply (DPS3) are disposed on the inter plate IN2, and, a second power supply (DPS2) and a fourth power supply (DPS4) are disposed on the inter plate IN3. As shown in FIG. 2, these data grounds on the inter plates are electrically connected.

However, one drawback of such configuration is that if one device such as DUT1 is interfered due to the noises, the other device like DUT2 will be affected also because with the same data (signal) ground. Consequently, the need to provide an interference-reduced IC testing system for devices under tests is necessary.

### SUMMARY OF THE INVENTION

It is a primary object of the present invention to provide an IC test apparatus for accurately and simultaneously testing at least two devices.

According to the claimed invention, the test apparatus includes a testing board having divided test sites and electrically disconnected data grounds on these test sites. At least two devices under test (DUTS) are disposed at different divided test sites on the testing board.

It is to be understood that both the forgoing general description and the following detailed description are exemplary, and are intended to provide further explanation of the invention as claimed. Other advantages and features of the invention will be apparent from the following description, drawings and claims.

### BRIEF DESCRIPTION OF THE DRAWINGS

FIG. 1 is a schematic diagram showing configuration of two devices: DUT1 and DUT2.

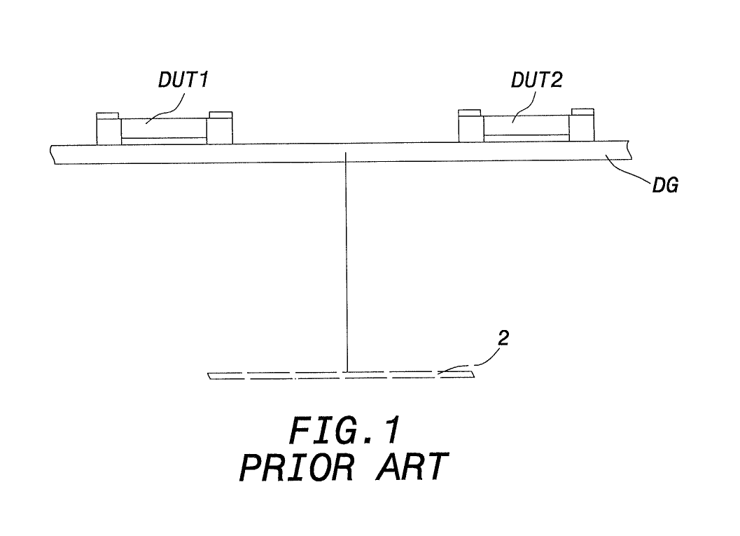

FIG. 2 is a cross-sectional, schematic view illustrating a prior art testing board structure.

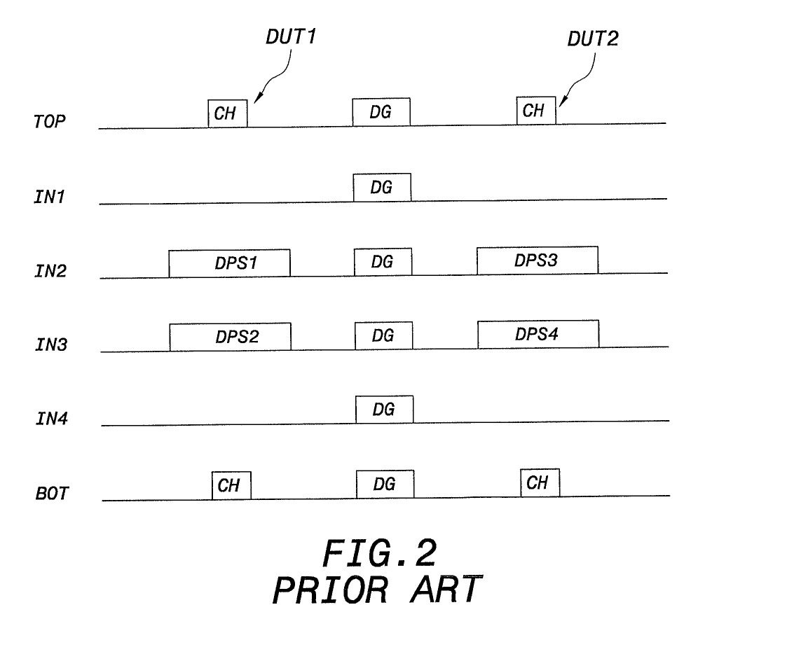

FIG. 3 is a diagram depicting arrangement of a testing board according to one preferred embodiment of this invention.

FIG. 4 is across-sectional, schematic diagram conceptually showing the testing board structure as depicted in FIG. 3 according to the present invention.

FIG. 5 is a schematic diagram conceptually illustrating connection between the devices under test and the power supply.

### DETAILED DESCRIPTION OF THE PREFERRED EMBODIMENT

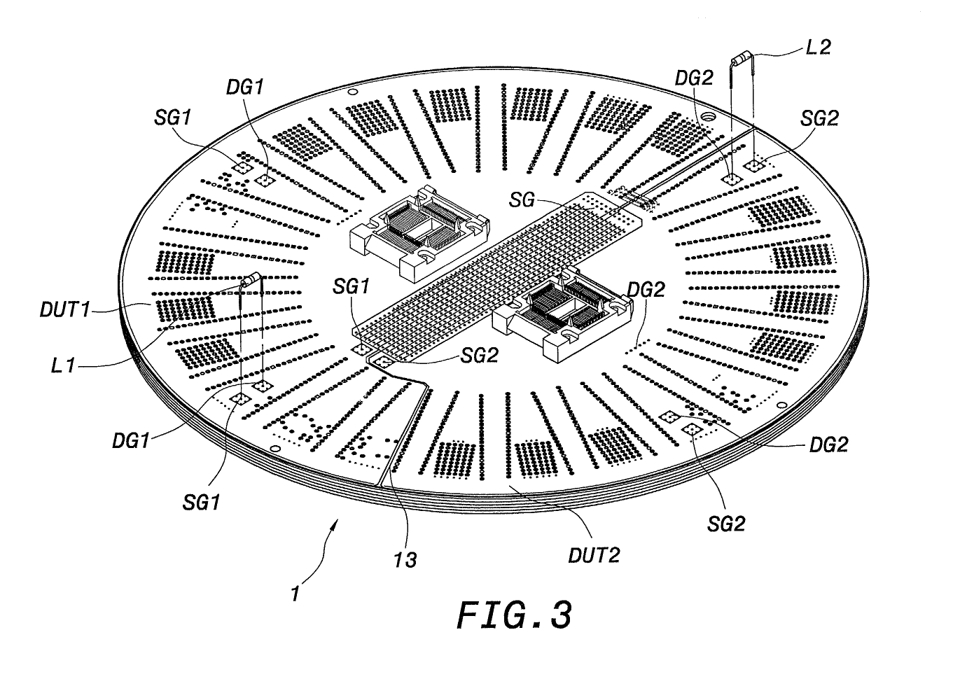

FIG. 3 is a diagram depicting arrangement of a testing board according to one preferred embodiment of this invention. As shown in FIG. 3, two devices, for example, DUT1 and DUT2, are mounted on different test sites of the testing board 1. Different test sites are distinguished by at least one distinguishing line 13, and each of the DUT1 and the DUT2 has its own grounds. In this embodiment, these grounds can be power grounds (SG) for grounding the power supply, signal grounds SG1 And SG2 for grounding the signals, reference grounds DG1 and DG2 for the purpose of grounding other devices.

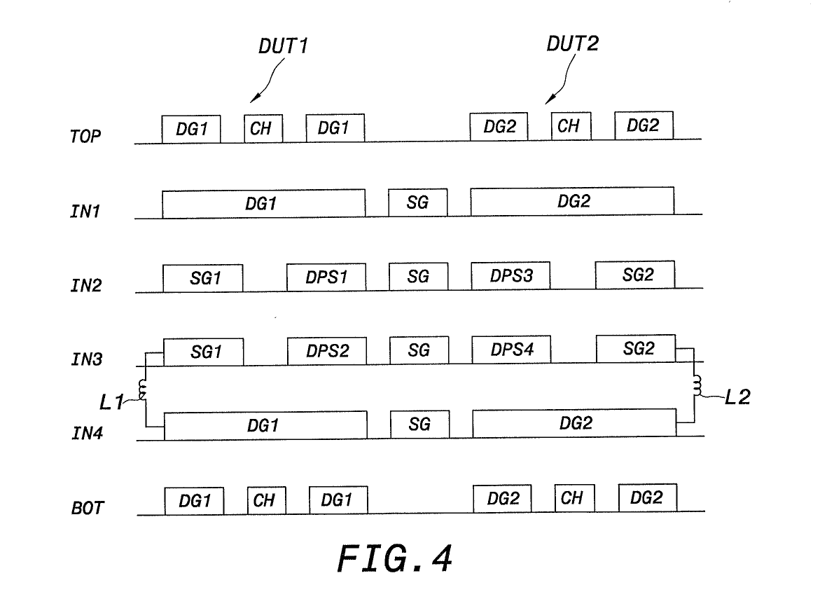

FIG. 4 is a cross-sectional, schematic diagram conceptually showing the testing board structure as depicted in FIG. 3 according to the present invention. In this embodiment, an exemplary six-layer testing board is demonstrated in FIG. 4. Note that this invention is not limited to six-layer testing boards. As shown in FIG. 4, reference grounds DG1 and DG2 are disposed on the TOP plate. On the second plate (IN1), a power ground SG for grounding the power supply (+5V and +15V) of the testing system is mounted between the reference grounds DG1 and DG2. On the third plate (IN2), signal grounds SG1 and SG2 for DUT1 and DUT2 respectively and device power supply DPS1 and DPS3 are disposed. Another power ground SG is located between the DPS1 and DPS2 on the third plate IN2. On the fourth plate (IN3), DUT signal grounds SG1 and SG2 for DUT1 and DUT2, respectively, and device power supply DPS2 and DPS4 are disposed on the fourth plate IN3 too. Another power ground SG is located between the DPS2 and DPS4 on the fourth plate IN3. On the fifth plate (IN4), reference grounds DG1 and DG2 are disposed. Another power ground SG is located between the reference grounds DG1 and DG2 on the fifth plate IN4. DUT signal grounds SG1 and SG2 on the fourth plate IN3 and the reference groundsDG1 and DG2 are electrically connected with magnetic devices like L1 and L2 respectively to form new reference grounds. Finally, on the bottom plate (BOT), reference grounds DG1 and DG2 for DUT1 and DUT2, respectively, are disposed. In this embodiment, the test site for DUT1 and the test site for DUT2 are both independent and devices DUT1 and DUT2 are with different and independent power grounds, signal grounds, and reference grounds. That is, noises affect DUT1 will not interfere DUT2 during testing.

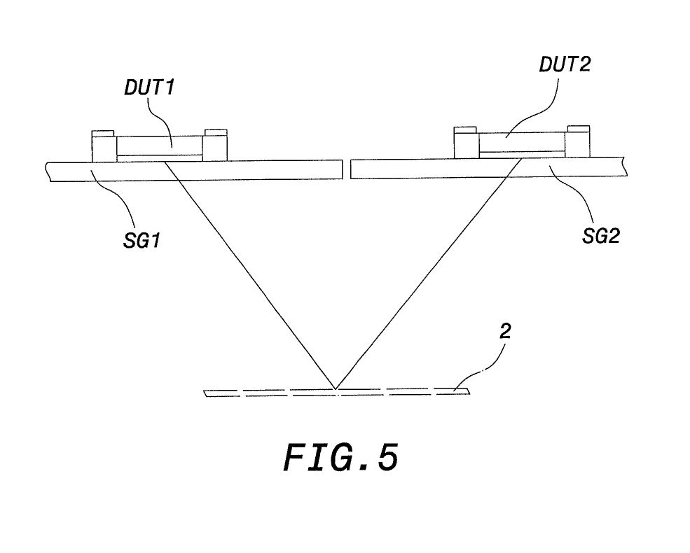

FIG. 5 is a schematic diagram conceptually illustrating connection between the devices under test and the power supply. In FIG. 5, DUT signal ground SG1 for DUT1 and DUT signal ground SG2 for DUT2 are coupled with the power supply ground 2. Since SG1 and SG2 are not connected, when one of the devices DUT1 or DUT2 is affected by the surrounding noises, noises will be attenuated by the power supply ground 2 and then feed back to the DUT1 or DUT2, lowering down the noise interferences and improving the test accuracy for the semiconductor devices.

In summary, it is advantageous to use the invention since 1) devices under test are mounted on different and independent test sites during testing on the testing board, and 2) testing accuracy is improved since aforementioned test sites respectively have at least one ground, which is independent with its counterpart on other divided testing sites. Note that this invention is not limited to testing board described in FIG. 3. Other testing board such as burn-inboard is also suitable for the claimed invention.

Those skilled in the art will readily observe that numerous modification and alterations of the device may be made while retaining the teachings of the invention. Accordingly, the above disclosure should be construed as limited only by the metes and bounds of the appended claims.

What is claimed is:

1. An integrated circuit test apparatus, comprising:
a testing board having at least two divided test sites thereon; and
at least two devices under test (DUT) disposed on corresponding said test site with at least one associated ground;
wherein noise interference is reduced for increasing DUT testing accuracy while testing.

2. The integrated circuit test apparatus of claim 1, wherein said ground is a single ground or a multi-ground.

3. The integrated circuit test apparatus of claim 2, wherein said multi-ground comprises power grounds, signal grounds, and reference grounds.

4. The integrated circuit test apparatus of claim 3, wherein said reference ground is coupled with a magnetic device for forming a new reference ground.

5. The integrated circuit test apparatus of claim 1, wherein said testing board is replaced with a burn-in board.
